(19) United States
(12) Patent Application Publication
(10) Pub. No.: US 2023/0130127 A1
(43) Pub. Date: Apr. 27, 2023

(54) METHOD FOR MANUFACTURING A FUNCTIONAL CHIP SUITABLE FOR BEING ASSEMBLED TO WIRE ELEMENTS

(71) Applicant: PRIMO1D, Grenoble (FR)

(72) Inventors: Skandar Abid, Echirolles (FR); Robin Lethiecq, Grenoble (FR); Daniele Sette, Grenoble (FR); Christopher Mackanic, Le Versoud (FR)

(21) Appl. No.: 17/756,325

(22) PCT Filed: Nov. 5, 2020
(86) PCT No.: PCT/FR2020/052001

§ 371 Date: Oct. 26, 2022

(30) Foreign Application Priority Data
Nov. 22, 2019 (FR) 1913132

(51) Int. Cl. H01L 23/66; H01L 21/78; H01L 23/544

(52) U.S. Cl. CPC H01L 23/66; H01L 21/78; H01L 23/544; H01L 2223/5446; H01L 2223/6677; H01Q 1/2225

(57) ABSTRACT

The invention relates to a functional chip (100) of which at least two electrical connection pads (11a, 11b) are intended for being connected to wire elements (40a, 40b). Said chip comprises: —a substrate (10) comprising a microelectronic component electrically connected to the two electrical connection pads arranged on a front face of said substrate (10), —a cover (20) comprising a first portion (21) assembled to the front face of the substrate (10), said first portion (21) forming a spacer between the two electrical connection pads; the cover (20) further comprising a second portion (22) spaced apart from the front face of the substrate (10) and extending opposite each electrical connection pad only partially, so as to allow access to said pads, along an axis (z) normal to the front face of the substrate (10). The invention likewise relates to a method for manufacturing such a functional chip.

### FIELD OF THE INVENTION

The present invention relates to a functional chip suitable for being connected to conductive wire elements and facilitating access to its connection pads prior to the assembly with the wire elements. It also relates to a method for manufacturing such a chip.

### TECHNOLOGICAL BACKGROUND OF THE INVENTION

Radiofrequency transmission-reception microelectronic devices are now commonly used for purposes of remote identification of objects with which these devices are associated. These are often referred to as electronic tags (“RFID tag”). The functionalities of such electronic tags may be limited to transmitting an identifier, or may include more complex functions such as the remote transmission of results of measurements carried out by sensors integrated into the chip, the processing of data received from a remote element, etc.

We know, for example, from documents U.S. Pat. Nos. 8,093,617, 8,471,773, 8,723,312, US2015318409, U.S. Pat. Nos. 8,782,880, 8,814,054 or US2015230336, the assembly technology of a wire and a chip designated by the trade name E-THREAD™.

According to this technology, the chip is provided with a lateral groove and a longitudinal section of the wire is inserted into this groove. The assembly can be obtained by embedding the wire in the groove, the dimensions of the wire and of the groove then being sufficiently adjusted to mechanically secure the two elements to one another. The assembly can also be obtained or reinforced by adding an adhesive material between the wire and the chip, or by soldering or brazing the wire and the chip.

In document U.S. Pat. No. 8,093,617, the lateral groove can in particular be obtained by assembling two elementary chips each comprising a small base and a large parallel base connected by at least one inclined side face; assembling the elementary chips by their small bases allows constitution of the lateral groove of the chip. In document US2015230336, the assembly of a chip and a cover made from a stack of electrically insulating layers also allows formation of at least one lateral groove. In document US2011001237, the chip comes from the assembly of a microelectronic component and a plywood substantially of the same dimensions and connected by a spacer, the spacer having dimensions smaller than those of the component; its placement allows natural obtainment of at least one lateral groove in the chip. Document WO2018138437 discloses an assembly method between a chip 110 having grooves 3a, 3b and wire elements 4a, 4b, as illustrated in FIGS. 1a and 1b. The chip 110 comprises, on the one hand, a substrate 1 comprising a functional circuit at its main face having electrical connection pads 1a, 1b, and on the other hand, a cover 2 having a T-shaped section, the foot of the T being assembled with the main face of the substrate 1.

The aforementioned chips of the state of the art are usually derived from a structure in the form of a 200 mm or 300 mm diameter wafer, comprising a plurality of collectively manufactured electronic components. The cutting of said structure, usually carried out by laser, makes it possible to single out each chip provided with its grooves.

The grooves 3a, 3b arranged in the chips 110 according to the state of the art are advantageous in that they form an effective receiving zone for the wire elements 4a, 4b; they nevertheless have the drawback of difficult access to the connection pads 1a, 1b of the chip 110, since the pads, intended to be connected to the wire elements 4a, 4b, are partially enclosed in the grooves 3a, 3b. The functionality tests of the microelectronic component of the chip 110, after singulation, are therefore complex or even impossible to perform before assembly with the wire elements 4a, 4b.

Moreover, when the chip 110 is assembled with the wire elements 4a, 4b, that is to say, when the wire elements 4a, 4b are arranged in the grooves 3a, 3b and secured to the connection pads 1a, 1b, it is usual to encapsulate all or part of said assembled chip to reinforce the mechanical strength between the chip 110 and the wire elements 4a, 4b. The encapsulating layer used penetrates with difficulty to the bottom of the grooves 3a, 3b proposed by the state of the art and therefore does not allow optimization of the mechanical strength between chip 110 and wire elements 4a, 4b.

### SUBJECT MATTER OF THE INVENTION

The present invention aims to remedy all or part of the stated drawbacks of the state of the art. It relates in particular to a functional chip facilitating access to its connection pads before assembly with the wire elements, and whose geometry allows improvement of the mechanical strength between the chip and the wire elements. It also relates to a method of manufacturing said chip.

### BRIEF DESCRIPTION OF THE INVENTION

The invention relates to a method for manufacturing a functional chip comprising the following steps:
supplying a collective structure formed by a cover substrate assembled on a support substrate, said structure defining a plurality of functional chips,
singulating the functional chips, each chip comprising at least two electrical connection pads intended to be connected to wire elements.
   The manufacturing method is remarkable in that:
the support substrate comprises a plurality of microelectronic components, each belonging to a chip, and has, on its front face, at least two electrical connection pads associated with a microelectronic component, scribe lines separating the microelectronic components belonging to neighboring chips, and a first protective layer placed on the microelectronic components outside the scribe lines and the connection pads;
the cover substrate comprises first portions, assembled to the front face of the support substrate via an adhesive layer, and a second part at a distance from the front face of the support substrate, each first portion forming a spacer between two electrical connection pads of a micro-electronic component;
functional chip singulation comprises forming a mask on a free face of the collective structure, defining protected zones and unprotected zones, and comprises dry, plasma or reactive ion bombardment etching of the cover substrate and of the support substrate, plumb with the unprotected zones.

The protected zones are arranged either plumb with the first portions, or plumb with the first portions and second portions included in the second part of the cover substrate. In the latter case, the second portions extend opposite the electrical connection pads and are crenellated to allow access to said pads along an axis normal to the front face of the support substrate.

The method according to the present invention allows the development of functional chips with very advantageous structural characteristics. In particular, it allows the realization of cover configurations giving direct and easy access to the electrical connection pads of the chips and promoting the coating with polymer or resin of the chips assembled with the wire elements, and therefore their mechanical strength.

According to other advantageous and non-limiting features of the invention, taken alone or in any technically feasible combination:
the support substrate comprises a wafer made of semiconductor material, in particular silicon;
the cover substrate comprises a wafer made of semiconductor material, in particular silicon, or of insulating material, in particular glass or sapphire;
the first portions comprise, on flanks substantially normal to the front face of the support substrate, a second protective layer;
the internal face, facing the front face of the support substrate, of the second part of the cover substrate comprises a second protective layer;
the support substrate and the cover substrate each comprise a wafer made of semiconductor material of the same nature, and the dry etching of the functional chip singulation step is done in a single treatment;
after the singulation of the functional chips, each chip comprises a cover from the cover substrate and a support from the support substrate, and the method then comprises a step of assembling each chip with two wire elements, each wire element being arranged in a groove delimited by a side of a first portion of the cover and a zone on the front face of the support occupied by the electrical connection pad, or by a second portion of the cover, a flank of a first portion of the cover and a zone on the front face of the support occupied by the electrical connection pad;
the method comprises depositing a resin or polymer layer on all or part of the chip and on the wire elements, to reinforce the mechanical strength between said chip and said wire elements;
at least one microelectronic component of a chip comprises two pairs of electrical connection pads and the first portion of the cover substrate, which forms a spacer between said two pairs, comprises an extension forming a second spacer between individual connection pads of a pair of electrical connection pads.

The present invention further relates to a functional chip whereof at least two electrical connection pads are intended to be connected to wire elements. Said chip comprises:
a support comprising a microelectronic component electrically connected to the two electrical connection pads arranged on a front face of said support,
a cover consisting of a first portion assembled to the front face of the support via an adhesive layer. Said first portion forms a spacer between the two electrical connection pads, so as to allow access to said pads, along an axis normal to the front face of the support.

The present invention lastly relates to a functional chip whereof at least two electrical connection pads are intended to be connected to wire elements. Said chip comprises:
a support comprising a microelectronic component electrically connected to the two electrical connection pads arranged on a front face of said support,
a cover comprising a first portion assembled to the front face of the support via an adhesive layer. Said first portion forms a spacer between the two electrical connection pads. The cover further comprises a second portion at a distance from the front face of the support and extending only partially opposite each electrical connection pad, so as to allow access to said pads, along an axis normal to the front face of the support.

### BRIEF DESCRIPTION OF THE DRAWINGS

Other features and advantages of the invention will become apparent from the following detailed description of the invention, which is provided with reference to the appended figures, in which:

FIG. 1 shows a functional chip before (a) and after (b) assembly to wire elements, according to the state of the art;

FIG. 2 shows a functional chip according to a first variant of a first embodiment of the invention, before and after assembly with wire elements, respectively in perspective (a) and in top view (b);

FIG. 3 shows a functional chip according to a second variant of a first embodiment of the invention, before and after assembly with wire elements, respectively in perspective (a) and in top view (b);

FIG. 4 shows a functional chip according to a third variant of a first embodiment of the invention, before and after assembly with wire elements, respectively in perspective (a) and in top view (b);

FIG. 5 shows a functional chip according to a fourth variant of a first embodiment of the invention, before and after assembly with wire elements, respectively in perspective (a) and in top view (b);

FIG. 6 shows a functional chip according to a first variant of a second embodiment of the invention, before (a) and after (b) assembly with wire elements;

FIG. 7 shows a functional chip according to a first variant of a second embodiment of the invention, before (a) and after (b) assembly with wire elements;

FIGS. 8a to 8f show steps of the method for manufacturing a functional chip, according to the invention.

FIG. 9 shows a functional chip configuration assembled with wire elements according to the state of the art.

FIGS. 10a and 10b show a particular configuration of a functional chip assembled with wire elements, in accordance with the present invention.

FIG. 11 shows various possible forms of cover and support for a functional chip according to the invention. Note that the references are not repeated in each of the forms shown, the cover and the support of the illustrated chips being easily identifiable based on the references of the first form.

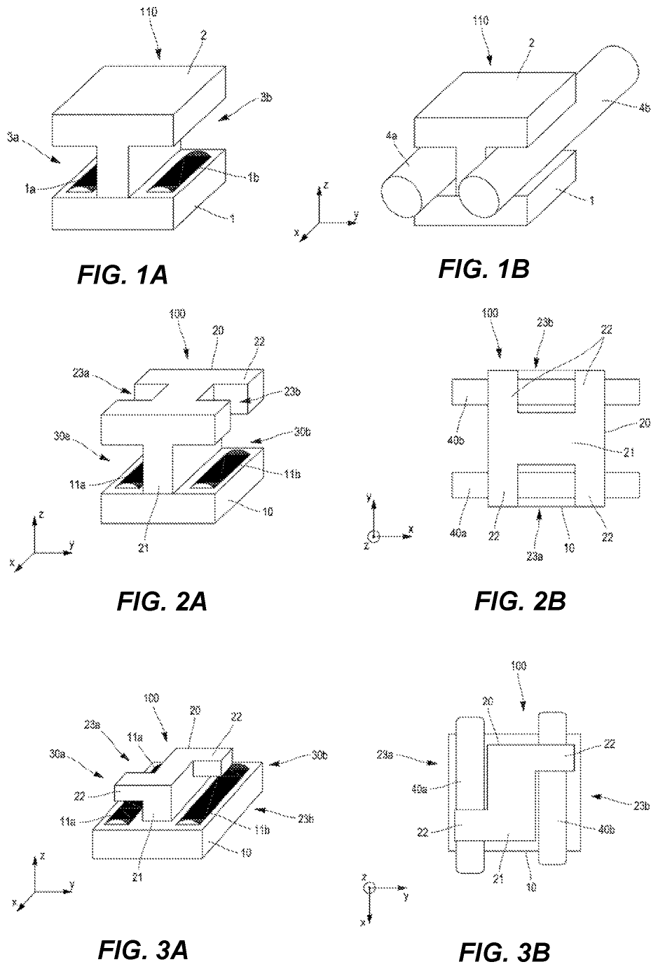

### DETAILED DESCRIPTION OF THE INVENTION

In the descriptive part, the same references in the figures may be used for the same type of elements. The figures are schematic representations which, for the sake of readability, are not to scale. In particular, the thicknesses of the layers or substrates along the z axis are not to scale with respect to the lateral dimensions along the x and y axes; and the relative thicknesses and lateral dimensions of the layers or substrates are not necessarily respected in the figures and between the figures.

The present invention relates to a functional chip 100 suitable for being assembled to conductive wire elements 40a, 40b (FIGS. 2 to 7). In general, said functional chip 100 comprises at least two electrical connection pads 11a, 11b, which are intended to be connected to two conductive wire elements 40a, 40b. Note that in the remainder of the description, the terms “wire elements” or “wires” may be used in an equivalent manner.

The functional chip 100 comprises a support 10 comprising at least one microelectronic component, which comprises the two electrical connection pads 11a, 11b arranged on a front face of said support 10. The connection pads 11a, 11b usually form blocks or bumps of metallic material, extra thick relative to the front face of the support 10 and connected to electrical contacts of the microelectronic component. The metallic material may for example consist of gold, copper, tin or tin alloys (SnPb, SnAgCu, SnAg, SnBi, SnIn, etc.).

The chip 100 further comprises a cover 20, a first portion 21 of which is assembled to the front face of the support 10, via an adhesive layer (not shown). As will be detailed later in the manufacturing method, the adhesive layer may in particular comprise a polymer.

The first portion 21 of the cover 20 forms a spacer between the two electrical connection pads 11a, 11b of the microelectronic component. It extends, in the plane of the front face of the support 10, along a longitudinal axis x, which is the separation axis between the two connection pads 11a, 11b. Advantageously, the first portion 21 is narrower than the spacing, along the transverse axis y, between the connection pads 11a, 11b, in order to avoid contact between the cover 20 and one or the other of the pads 11a, 11b. In the plane of the front face of the support 10, the first portion 21 is preferentially spaced apart from the connection pads 11a, 11b, by a few microns to a few tens of microns. The first portion 21 may have the same dimension as the support 10 along the longitudinal axis x, or alternatively be of smaller dimension, as illustrated in certain variant embodiments.

According to a first embodiment of the functional chip 100, several variants of which are shown in FIGS. 2 to 5, the cover 20 comprises a second portion 22 at a distance from the front face of the support 10 and extending overhanging at least one electrical connection pad 11a, 11b. This second portion 22 has the particularity of being only partially opposite each pad 11a, 11b, so as to allow access to said pads, along a z axis normal to the front face of the support 10. In top view, the second portion 22 of the cover 20 thus appears crenellated, having openings 23a, 23b, 23a′, 23b′ that facilitate vertical access (along the z axis) to the connection pads 11a, 11b, 11a′, 11b′. It is thus possible to test the functionality of the chips 100 individually and prior to their assembly with the wire elements 40a, 40b.

In general, an opening 23a, 23b, 23a′, 23b′ has a dimension along the longitudinal axis x of the order of a few tens of microns to a few hundreds of microns, depending on the size of the chip 100; along the transverse axis y, the opening 23a, 23b, 23a′, 23b′ preferentially extends as far as the first portion 21. This in particular has an advantage for the mechanical strength between the chip 100 and the wire elements 40a, 40b because the layer of resin or polymer, which is intended to be deposited on all or part of the cover 20 and the wire elements 40a, 40b to secure them together, can more effectively encompass the wire elements by creeping between the first portion 21 and the wires 40a, 40b, up to the front face of the support 10.

The presence of the overhangs, included in the second portion 22 of the cover 20, above the pads 11a, 11b, allows the grooves 30a, 30b to be defined in which the wire elements 40a, 40b will be easily arranged and guided to be assembled to the pads 11a, 11b.

The second portion 22 of the cover 20 can have different shapes in the plane (x,y); without this being exhaustive, certain forms are described below, in possible variants of the first embodiment of the present invention.

In a first variant illustrated in FIG. 2, the cover 20 of the functional chip 100 has an H shape, in top view (along the plane (x,y)). The first portion 21 of the cover 20 corresponds to the central part of the H and is secured to the front face of the support 10. The second portion 22 here is composed of four overhangs extending from the first portion 21 above the connection pads 11a, 11b. The openings 23a, 23b in the second portion 22 are substantially centered, plumb with the connection pads 11a, 11b, and facilitate vertical access (along the z axis) to said pads 11a, 11b. However, the second portion 22, the first portion 21 and the front face of the support 10 define a longitudinal groove 30a, 30b, on each side of the functional chip 100, to facilitate the placement and the housing of the wire elements 40a, 40b.

In a second variant of the first embodiment, illustrated in FIG. 3, the cover 20 of the functional chip 100 has an S shape in top view. The first portion 21 of the cover 20 secured to the front face of the support 10 extends along the longitudinal axis x. Note that, in this example, the dimension along the longitudinal axis x of the first portion 21 is less than that of the support 10, but that this longitudinal dimension is in no way linked to the shape of the cover 20 and can be implemented in the different embodiments.

The second portion 22 here is composed of two overhangs extending from the first portion 21 above the connection pads 11a, 11b, at each end of the first portion 21 along the longitudinal axis x. The openings 23a, 23b in the second portion 22, plumb with the connection pads 11a, 11b, facilitate vertical access (along the z axis) to said pads. The second portion 22, the first portion 21 and the front face of the support 10 still define a longitudinal groove 30a, 30b, on each side of the functional chip 100, to house the wire elements 40a, 40b.

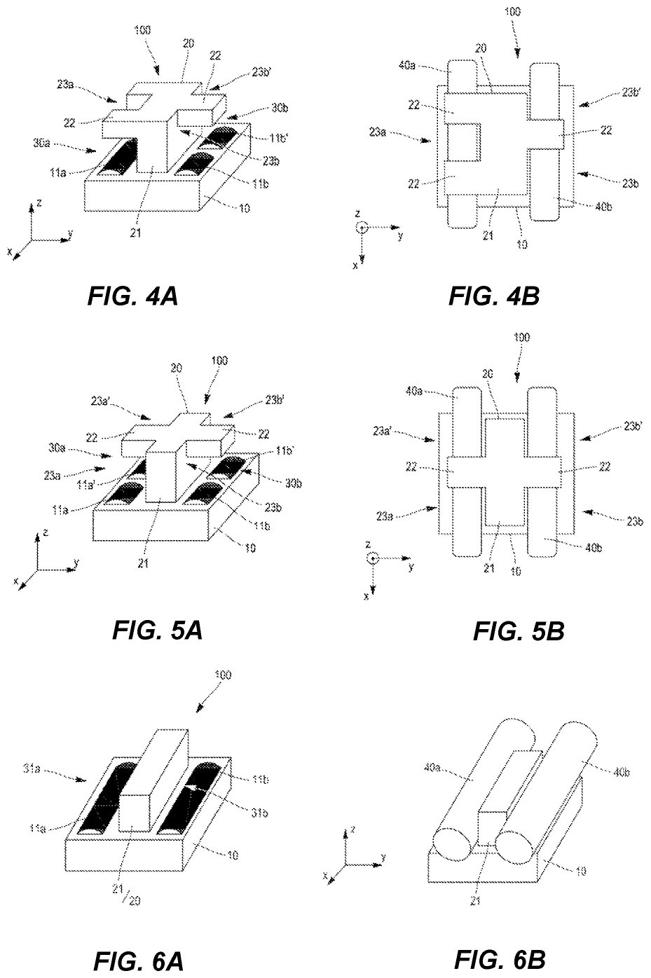

In a third variant of the first embodiment, illustrated in FIG. 4, the cover 20 of the functional chip 100 has a Y shape, in top view. The first portion 21 of the cover 20 secured to the front face of the support 10 extends along the longitudinal axis x. The second portion 22 here is composed of three overhangs extending from the first portion 21 above the connection pads 11a, 11b. A first opening 23a in the second portion 22 is located directly above a first connection pad 11a, disposed on one side of the chip 100. Second and third openings 23b, 23b′ respectively provide vertical access to two other connection pads 11b, 11b′ arranged on the other side of the chip 100. An overhang of the second portion 22 extends above the front face of the support 10, substantially between the two pads 11b, 11b′. Note that the presence of a pair of connection pads 11b, 11b′ on one side of the chip 100 is given as an example; it is entirely possible for there to be only one connection pad 11b on this side of the chip 100.

The second portion 22, the first portion 21 and the front face of the support 10 define a longitudinal groove 30a, 30b, on each side of the functional chip 100, to house the wire elements 40a, 40b.

In a fourth variant of the first embodiment, illustrated in FIG. 5, the cover 20 of the functional chip 100 has a cross shape, in top view. The first portion 21 of the cover 20 secured to the front face of the support 10 extends along the longitudinal axis x, between the connection pads. The second portion 22 here is composed of two overhangs that are symmetrical with respect to the longitudinal axis x, and extending from the first portion 21 above the front face of the support 10. In the example illustrated, the chip 100 has two pairs of connection pads, a first pair 11a, 11a′ on one side and a second pair 11b, 11b′ on the other side. Two openings 23a, 23a′ in the second portion 22 are respectively located plumb with the two pads 11a, 11a′ of the first pair and two openings 23b, 23b′ are respectively located plumb with the two pads 11b, 11b′ of the second pair. These openings 23a, 23a′, 23b, 23b′ provide vertical access to the plurality of connection pads. The two overhangs of the second portion 22 extend above the front face of the support 10, substantially between the two pads of each pair.

The second portion 22, the first portion 21 and the front face of the support 10 define a longitudinal groove 30a, 30b, on each side of the functional chip 100, to house the wire elements 40a, 40b.

Of course, all the possible variants of this first embodiment of the invention have not been described and one could imagine other configurations and arrangements for the second portion(s) 22, and for the connection pads 11a, 11a′, 11b, 11b′.

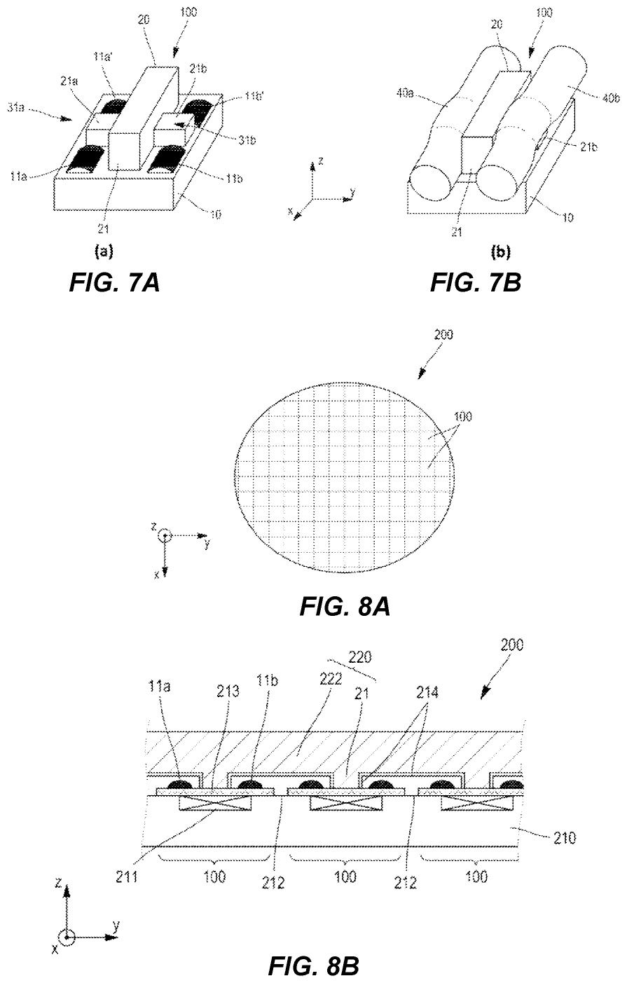

According to a second embodiment of the invention, two variants of which are shown in FIGS. 6 and 7, the cover 20 consists only of the first portion 21, assembled to the front face of the support 10. The first portion 21 forms a spacer between the (at least) two electrical connection pads 11a, 11b, located on each side of the functional chip 100. There is no second portion plumb with the electrical connection pads 11a, 11a′, 11b, 11b′, unlike the first embodiment previously described.

The functional chip 100 according to this second embodiment allows direct vertical access (along the z axis) to the connection pads 11a, 11a′, 11b, 11b′, along an axis normal z to the front face of the support 10.

FIG. 6 illustrates a first variant of the second embodiment. The first portion 21 is only formed by a longitudinal spacer, that is to say, extending along the x axis, inserted between the connection pads 11a, 11b. In this example, the longitudinal dimension (along the x axis) of the first portion 21 is less than the longitudinal dimension of the support 10. Of course, nothing prevents these dimensions from being identical.

The first portion 21 and the front face of the support 10 define a longitudinal half-groove 31a, 31b, on each side of the functional chip 100, to house the wire elements 40a, 40b. Advantageously, a shim (not shown) can be temporarily associated with the functional chip 100 so as to define a groove and facilitate the positioning and securing of the wire elements 40a, 40b to the connection pads 11a, 11b, during the chip 100-wire 40a, 40b assembly. For example, the shim may consist of a flat body placed against the free upper surface of the first portion 21, located in a plane parallel to the plane of the front face of the support 10, thus defining said groove with the first portion 21 and the front face of the support 10. According to another example, the shim may comprise two flat lateral bodies placed on each side of the functional chip 100, substantially parallel to the first portion 21, and defining a groove with the first portion 21 and the front face of the support 10.

FIG. 7 illustrates a second variant of the second embodiment. The cover 20 still consists of the first portion 21, assembled to the front face of the support 10, that is to say that it does not comprise a second portion 22 at a distance from the front face of the support 10 and facing the connection pads 11a, 11a′, 11b, 11b′. The first portion 21 in this variant extends, on the one hand, along the longitudinal axis x, between a first pair of pads 11a, 11a′ arranged on one side of the chip 100 and a second pair of pads 11b, 11b′. On the other hand, the first portion 21 comprises two extensions 21a, 21b that extend along the transverse axis y. The first extension 21a forms a spacer between the two pads 11a, 11a′ of the first pair of pads, and the second extension 21b forms a spacer between the two pads 11b, 11b′ of the second pair of pads.

Note that the extensions 21a, 21b have a height along the normal axis z less than the height of the central longitudinal part of the first portion 21. As a result, the central longitudinal part of the first portion 21 and the front face of the support 10 define a longitudinal half-groove 31a, 31b, on each side of the functional chip 100, to place the wire elements 40a, 40b. Advantageously, like for the first variant described above, a shim (not shown) can be temporarily associated with the functional chip 100, so as to define a groove with the first portion 21 and the front face of the support 10 and thus facilitate the positioning and securing of the wire elements 40a, 40b on the connection pads 11a, 11b during the chip 100-wire 40a, 40b assembly.

Although the second variant of the second embodiment is described with a first portion 21 comprising two extensions 21a, 21b, it is entirely possible to provide only one extension, on only one side of the chip 100. In such a case, the other side, devoid of extension, may comprise a single connection pad, instead of the pair of connection pads described.

An extension 21a of the first portion 21 may have an advantage in certain assembly configurations of the functional chips 100 with the wire elements 40a, 40b. Indeed, when the wire 40a is fixed to the connection pad 11a or to the pair of connection pads 11a, 11a′, it may be necessary to cut said wire to disconnect two strands of the wire element. This is for example the case for an RFID tag, in which it is necessary to cut at least one of the two wires connected to the chip 100, close to the chip 100. The extension 21a, on which the wire 40a is arranged, can serve as a promontory allowing securing of a step of cutting the wire 40a, limiting the risks of damage and weakening of the support 10.

For one or another of the embodiments and variants of the present invention stated above, the materials of the cover 20 and of the support 10 of a functional chip 100 may be of various natures. For example, the support 10 can come from a wafer made of semiconductor material, in particular silicon, in which and on which the microelectronic component(s) of the chip 100 is (are) manufactured. Of course, other semiconductor materials may be considered depending on the intended type and properties of the chip 100.

Also as an example, the cover 20 can come from a wafer made of semiconductor material, in particular silicon, or from insulating material, in particular glass or sapphire. Of course, these lists of materials are not exhaustive and can be extended to all building materials of interest, depending on the targeted properties of the cover 20 of the chip 100.

In general, the lateral dimensions of a functional chip 100, in the plane (x,y) of the front face of the support 10, are between 300 and 800 microns; the thickness of a chip 100, along the z axis normal to the front face of the support 10, is typically between 300 and 500 microns.

Each functional chip 100 is intended to be assembled with two wire elements 40a, 40b, each wire element 40a, 40b being arranged in a groove 30a, 30b or half-groove 31a, 31b. According to the first embodiment of the invention, each groove 30a, 30b is delimited by a second portion 22, a flank of the first portion 21 and a zone on the front face of the support 10 occupied by the electrical connection pad 11a, 11b. According to the second embodiment of the invention, each half-groove 31a, 31b is delimited by a flank of the first portion 21 and a zone on the front face of the support 10 occupied by the electrical connection pad 11a, 11b.

During the assembly step, each connection pad 11a, 11b passes through a molten state, allowing it to be secured to a wire 40a, 40b after it has solidified.

The functional chip 100, thus secured to the wire elements 40a, 40b, is then covered with a layer of resin or polymer, on all or part of the cover 20 and on the wires 40a, 40b, so as to ensure the mechanical strength between the chip 100 and said wire elements 40a, 40b. The presence of openings 23a, 23a′, 23b, 23b′ in the cover 20 (first embodiment) or the absence of a second portion 22 (second embodiment) allows this resin or polymer layer to insinuate itself between the flanks of the first portion 21 and the wires 40a, 40b, up to the front face of the support 10, which has the effect of further reinforcing the mechanical strength between the chip 100 and said wire elements 40a, 40b.

The present invention also relates to a method of manufacturing a functional chip 100 intended to be assembled with wire elements 40a, 40b. As mentioned previously, such a chip 100 is formed by a support 10 and a cover 20, and comprises at least two electrical connection pads 11a, 11b intended to be connected to the wire elements 40a, 40b. It further comprises at least one microelectronic component produced in and/or on the support 10.

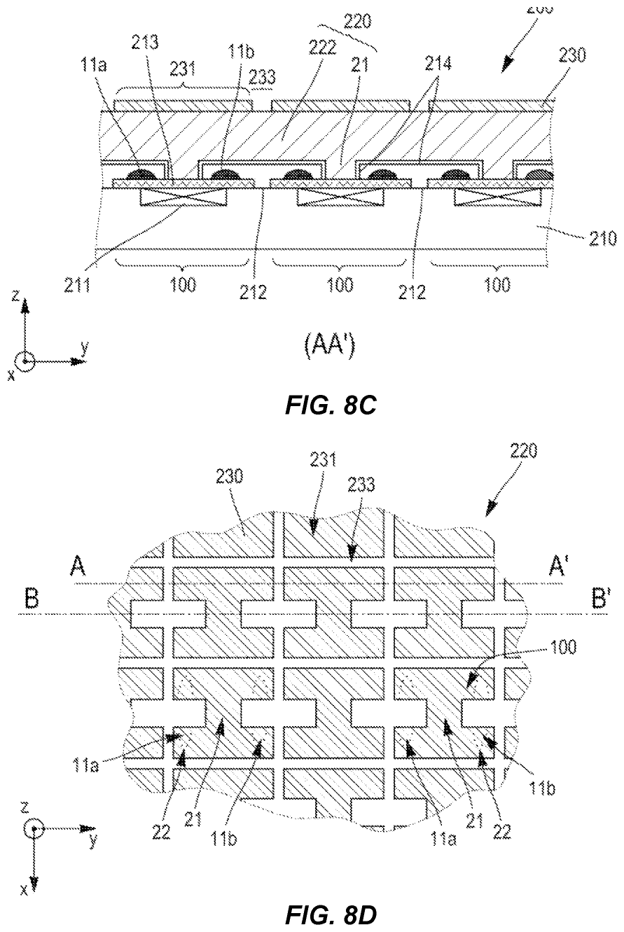

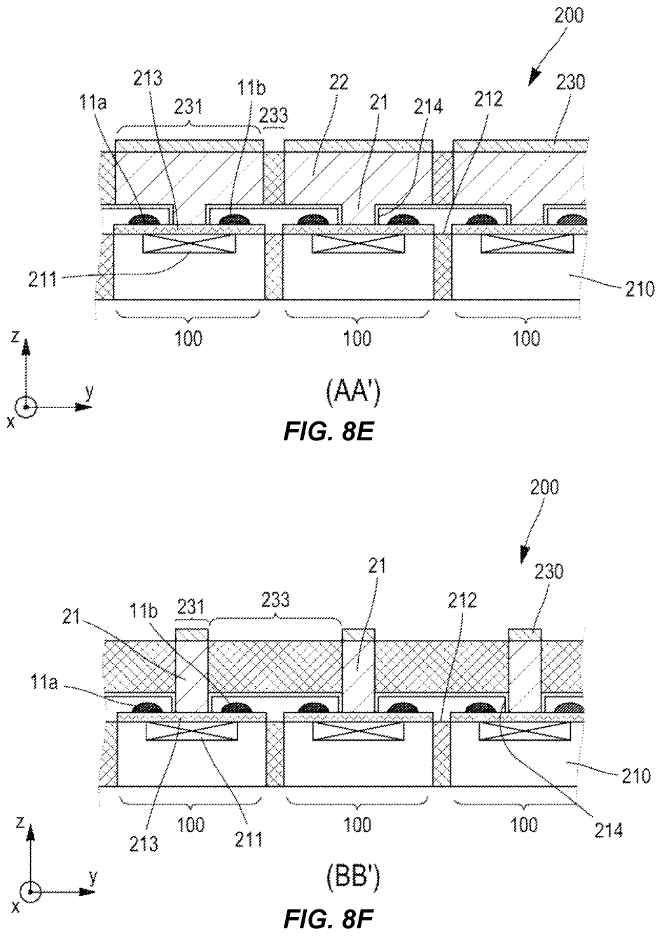

The manufacturing method according to the invention firstly comprises a step of supplying a collective structure 200 formed by a cover substrate 220 assembled on a support substrate 210. Said structure 200 is qualified as collective because it defines a plurality of functional chips 100, as shown schematically in FIGS. 8a and 8b.

The support substrate 210 is advantageously formed by at least one wafer made from semiconductor material, in particular silicon. Generally, the diameter of the wafer is 150, 200 or 300 mm, possibly even 450 mm for the next generations.

The support substrate 210 comprises a plurality of microelectronic components 211 produced in and/or on said wafer, each component belonging to a chip 100 (FIG. 8b). By way of example and without limitation, the microelectronic component 211 may consist of a radiofrequency transmission-reception device, a computing device, a sensor, an LED or any other form of integrated circuit produced on the support substrate 210, using techniques known in the semiconductor field. For the sake of clarity, only the steps and elements useful for understanding the method according to the invention have been shown and will be described. In particular, the development of the microelectronic components 211 has not been detailed, the invention being compatible with the usual manufacturing methods.

The support substrate 210 has a plurality of electrical connection pads 11a, 11b on its front face. At least two electrical connection pads 11a, 11b are electrically connected to a microelectronic component, by means of contact tracks or conductive vias formed on or in the support substrate 210. The support substrate 210 also has, on its front face, scribe lines 212 separating the microelectronic components 211 belonging to neighboring chips 100, and a first protective layer 213 placed on the microelectronic components 211. The first protective layer 213 is not present in the scribe lines 212, nor on the connection pads 11a, 11b.

By way of example, the scribe lines 212 delimit microelectronic components 211 whose dimensions, in the plane (x,y) of the front face of the support substrate 210, are between 300 and 800 microns. Depending on the diameter of the wafer forming the support substrate 210, the collective structure 200 can define between a few hundred and a few hundred thousand functional chips 100.

The cover substrate 220 is advantageously formed by at least one wafer of semiconductor material, for example silicon, or of insulating material, for example glass or sapphire. Of course, other materials could be considered depending on the constraints and properties required by the application. Like for the support substrate 210, the wafer diameter can be 150, 200 or 300 mm, or even 450 mm.

The cover substrate 220 comprises first portions 21, assembled to the front face of the support substrate 210 via an adhesive layer (not shown), and a second part 222 at a distance from the front face of the support substrate 210 (FIG. 8b). Each first portion 21 forms a spacer between two electrical connection pads 11a, 11b of a microelectronic component 211. Typically, a distance of a few microns to a few tens of microns separates the first portion 21 from the connection pads 11a, 11b.

Advantageously, the assembly between the cover substrate 220 and the support substrate 210 is performed by a known polymer bonding technique. A layer of polymer (for example epoxy, photosensitive resin, polymethyl methacrylate (PMMA), polydimethylsiloxane (PDMS), polyimides, etc.) is deposited on the surfaces to be assembled of the first portions 21 of the cover substrate 220. The cover substrate 220 and the support substrate 210 are then brought face to face with each other, with an alignment precision of plus or minus 10 microns, or even an alignment precision of plus or minus 5 microns. In other words, the alignment between the assembled substrates is aimed at better than 10 microns, or even better than 5 microns. Indeed, it is important that the first portions 21 form spacers between the connection pads 11a, 11b, without coming into contact with said pads 11a, 11b. A pre-alignment is therefore required before joining the cover 220 and support 210 substrates. Thus pre-aligned, the cover 220 and support 210 substrates are brought into contact and bonded, for example by thermocompression and under a controlled atmosphere.

Alternatively, the assembly between the cover substrate 220 and the support substrate 210 can be carried out by another known bonding technique, for example anodic bonding, bonding by metal welding or ultrasonic bonding.

Regardless of the assembly technique chosen, the cover 220 and support 210 substrates are advantageously cleaned prior to bringing them into contact and prior to depositing the adhesive layer. The cleaning may for example comprise conventional sequences based on ozone, SC1 (standard clean 1), SC2 (standard clean 2), to respectively remove organic, particulate and metallic contamination present on one and/or the other of the substrates. Surface activation by oxygen plasma can also be applied prior to assembly.

In general, the first portions 21 have flanks that are substantially normal to the front face of the support substrate 210, and advantageously comprise a second protective layer 214 on said flanks. Also advantageously, the internal face of the second part 222 of the cover substrate 220, that is to say, the face facing the front face of the support substrate 210, also comprises the second protective layer 214.

This second protective layer 214 has the advantage of protecting the exposed surfaces of the cover substrate 220 during the etching carried out in a subsequent singulation step of the chips 100 of the manufacturing method.

Preferably, the collective structure 200 is thinned, at one and/or the other of its free faces, namely the rear face of the support substrate 210 and the rear face of the cover substrate 220. It is advantageous to manufacture functional chips 100 of low thickness along the z axis normal to the front face of the support substrate 210, typically between 300 and 500 microns. The wafers forming the support 210 and cover 220 substrates usually have an initial thickness of the order of 400 to 800 microns each. It is therefore advantageous to thin the collective structure 200, prior to the singulation of the chips 100, down to the target thickness of the chips 100, a collective thinning being easier and more effective. The thinning of the collective structure 200 can be done by mechanical lapping (“grinding”), by chemical etching and/or by chemical mechanical polishing.

The manufacturing method according to the invention then comprises a step of singulating the functional chips 100 of the collective structure 200.

Functional chip 100 singulation comprises forming a mask 230 on a free face of the collective structure 200. For example, the mask 230 can be formed on the rear face (face opposite its front face, when assembled) of the cover substrate 220, as illustrated in FIG. 8c. Alternatively, the mask 230 could have been formed on the rear face (face opposite its front face, when assembled) of the support substrate 210.

The mask 230 is for example formed from a material chosen from among silicon nitride, silicon oxide, polyimides, photosensitive resins, etc. It defines protected zones 231 and unprotected zones 233: an example of a mask 230 is illustrated in FIG. 8c in section and in FIG. 8d in top view.

The chip 100 singulation step then comprises dry anisotropic etching, by plasma or by reactive ion bombardment, applied to the collective structure 200, which will etch said structure plumb with the unprotected zones 233.

This type of dry etching generally takes place in a single-plate etching chamber, in which one free face of the collective structure 200 is exposed to the etching atmosphere and the other free face is placed on a holding plate or an adhesive backing film.

By way of example, to etch a silicon material, it is possible to implement a known etching according to the Bosch method, based on alternating etching sequences (SF6 reactive gas) and passivation sequences (C4F8 reactive gas). To etch a material made from silica, silicon oxide or nitride, CF4 or SF6 will be used, for example, as reactive gas.

The dry etching will thus etch the cover substrate 220 and the support substrate 210, directly above the unprotected zones 233. As illustrated in FIGS. 8e and 8f, the hatched (cross-hatched) portions will typically be those etched during this step.

According to a first embodiment of the method, the protected zones 231 are arranged directly above the first portions 21 and plumb with the second portions 22 included in the second part 222 of the cover substrate 220. As can be seen in FIGS. 8d, 8e and 8f, the second portions 22 extend opposite the underlying electrical connection pads 11a, 11b, but are crenellated to allow access to said pads 11a, 11b, along an axis z normal to the front face of the support substrate 210. This first embodiment results in the manufacture of a plurality of functional chips 100 according to the first embodiment stated above.

According to a second embodiment of the method, the protected zones 231 are arranged plumb with the first portions 21 and there is no protected zone plumb with the electrical connection pads 11a, 11b. The entire second part 222 of the cover substrate 220 plumb with the pads 11a, 11b is thus etched during the singulation step, leading to the manufacture of a plurality of functional chips 100 according to the second embodiment stated above.

When the support substrate 210 and the cover substrate 220 each comprise a wafer made of semiconductor material of the same nature, the dry etching of the singulation step is advantageously done in a single treatment.

Let us take the example of a support substrate 210 and a cover substrate 220 each comprising a silicon wafer. The collective structure 200 is placed in the etching chamber. An etching sequence adapted to the silicon material is thus capable of etching the second part 222 of the cover substrate 220 directly above the unprotected zones 233, then the support substrate 210 in the scribe lines 212, since these do not comprise the first protective layer 213. The electrical connection pads 11a, 11b are not etched because, formed from a metallic material, they are not sensitive to the etching atmospheres used for silicon. A single etching sequence can thus lead to the simultaneous singulation of the plurality of functional chips 100 defined in the collective structure 200.

Let us again consider the case where the support substrate 210 and the cover substrate 220 each comprise a silicon wafer; this time, the flanks of the first portions 21 comprise a second protective layer 214, as well as the internal face of the second part 222 of the cover substrate 220, as mentioned previously. The second protective layer 214 can be silicon oxide, silicon nitride, a polymer or other layer capable of protecting the underlying silicon from etching: it is therefore a layer ensuring high etching selectivity relative to the material making up the cover substrate 20. A first etching sequence suitable for the silicon material is applied, so as to etch the second part 222 of the cover substrate 220 plumb with the unprotected zones 233; a second etching sequence suitable for the material making up the second protective layer 214 is then applied, so as to pass through said second protective layer 214 placed on the internal face of the second part 222 at the unprotected zones 233. Finally, a third etching sequence suitable for the silicon material (which may or may not be identical to the first sequence) is applied to etch the support substrate 210 in the scribe lines 212. The three sequences can be chained, without removing the collective structure 200 from the etching chamber.

According to yet another example, the support substrate 210 and the cover substrate 220 respectively comprise a silicon wafer and a silica wafer. Two consecutive etching sequences, respectively adapted to etch the silica and to etch the silicon, can be applied to the collective structure 200 so as to etch the cover substrate 220, then the support substrate 210, to simultaneously singulate all the functional chips 100. Alternatively, the different etching sequences can be done separately, in two (or more) distinct steps, with removal of the collective structure 200 from the etching chamber.

Returning to the general description of the manufacturing method according to the present invention, whatever the material of the support 210 and cover 220 substrates of the collective structure 200, the plurality of functional chips 100 singulated is obtained after the dry etching. Recall that the collective structure 200 will preferably be placed on an adhesive layer (“tape”), prior to the dry etching step, so as to facilitate handling of the functional chips 100 after singulation.

The singulation step of the method is particularly advantageous compared to conventional laser cutting or mechanical sawing techniques, especially since the number of chips 100 per collective structure 200 is high, for example greater than 1000.

The dry etching implemented in the singulation step of the method is also advantageous in that it allows the production of covers 20 comprising openings 23a, 23a′, 23b, 23b′ opposite the electrical connection pads 11a, 11a′, 11b, 11b′, which the techniques conventionally used do not allow, without a very significant risk of damaging the underlying pads 11a, 11a′, 11b, 11b′.

The manufacturing method according to the invention allows the definition of very varied cover configurations, such as for example illustrated in FIGS. 2 to 7. The covers 20 of the functional chips 100 according to the first embodiment described above comprise openings 23a, 23a′, 23b, 23b′ facing the electrical connection pads 11a, 11a′, 11b, 11b′, formed during the same singulation step. Remember that these openings facilitate, on the one hand, vertical access to the connection pads 11a, 11a′, 11b, 11b′, and promote, on the other hand, the reinforcement of the mechanical strength between the chip 100 and the wires 40a, 40b to which it will be assembled, due to better coating by the layer of resin or polymer, as will be described below.

After the singulation step, each chip 100 comprises a cover 20 derived from the cover substrate 220 and a support 10 derived from the support substrate 210. Functionality tests of the chips 100 can be carried out at this stage, so as to sort out and isolate the chips 100 that are not functional or that have an insufficient performance level.

The manufacturing method can then comprise a step of assembling each chip 100 with two wire elements 40a, 40b, each wire element 40a, 40b being arranged in a groove 30a, 30b, or half-groove 31a, 31b, delimited by at least a second portion 22, a flank of a first portion 21 and a zone on the front face of the support 10 occupied by the electrical connection pad 11a, 11b (first embodiment of the method, and first embodiment of the functional chip 100), or by a flank of a first portion 21 and a zone on the front face of the support 10 occupied by the electrical connection pad 11a, 11b (second embodiment of the method, and second embodiment of the functional chip 100).

The securing takes place between the connection pads 11a, 11b and the wires 40a, 40b, due to the transition from a molten state to a solidified state of said pads 11a, 11b, the wires being held flat against the pads 11a, 11b during this state change phase. This phase could for example be brought about by application of a localized and time-limited heating. The chip 100 is thus secured to the wires 40a, 40b.

Following the chip 100-wire 40a, 40b assembly, the manufacturing method may comprise depositing an encapsulating layer 120 (FIG. 10b) of resin or polymer on all or part of the cover 20 and on the wire elements 40a, 40b, to reinforce the mechanical strength between the chip 100 and said wire elements 40a, 40b. By way of example, this layer can comprise epoxy, silicones, urethanes, acrylates, etc.

In practice, the encapsulating layer 120 can be dispensed around the chip 100 (and therefore around the cover 20) by material jet or by contact. This dispensing can be done in one or several stages. The shape of the layer 120 can be controlled by a previously filled mold into which the functional chip 100 assembled on the wires 40a, 40b is brought. The polymerization of the layer 120 is done by UV exposure or else by a heat treatment. The polymerization can be done in several successive exposures to control the properties of the encapsulating layer 120 or allow the form to be unmolded.

The manufacturing method according to the present invention is advantageous in that the encapsulating layer 120 is capable of insinuating itself between the flanks of the first portion 21 of the chip 100 and the wire elements 40a, 40b, as far as the front face of the support 10, to further reinforce the mechanical strength, compared to known practices of the state of the art.

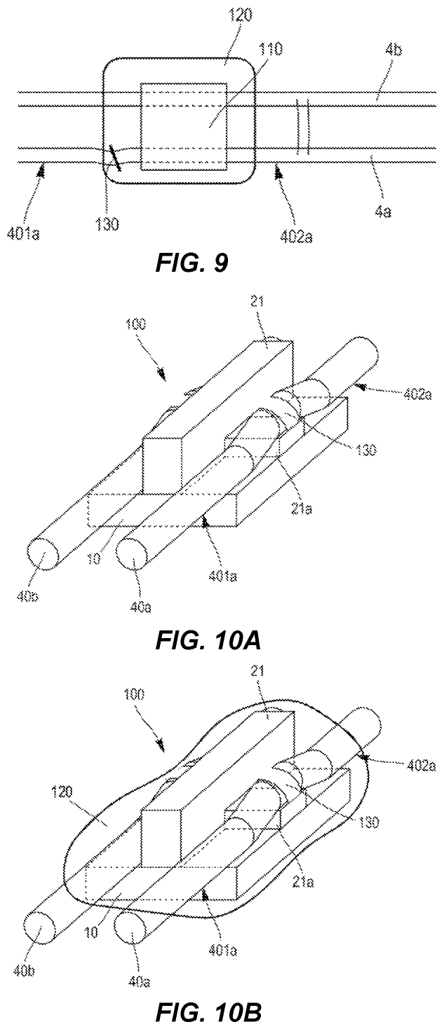

For certain applications (for example, RFID tag), it may be necessary to disconnect (electrically) one strand 401a of a wire element 40a from the other strand 402a, the two strands 401a, 402a being on either side of a connection pad 11a: as illustrated in FIG. 9, the practice of the state of the art is to make a notch 130 in said strand 401a after the chip 100 and the wire elements 4a, 4b have been assembled and coated by the encapsulating layer of resin or polymer 120. The drawback of this approach is that this notch 130 creates a weak point, liable to generate a mechanical separation between the strand 401a and the chip 100, which is not desirable.

The manufacturing method according to the present invention offers an alternative solution, based on the development of a functional chip 100 conforming to the second variant of the second embodiment described previously with reference to FIG. 7. In this case, the first portion 21 of the cover 20 of the chip 100 comprises at least one extension 21a, 21b forming a second spacer between individual connection pads of a pair of electrical connection pads.

After the electrical connection between the wire elements 40a, 40b and the connection pads 11a, 11a′, 11b, 11b′, the manufacturing method may comprise a step of cutting the wire 40a by laser or by mechanical sawing, plumb with the extension 21a, so as to disconnect the strand 401a from the other strand 402a of the wire element 40a (FIG. 10a). The coating by the resin or polymer layer 120 can then be carried out (FIG. 10b). The notch 130 between the strands 401a, 402a allows electrical disconnection, and its positioning in the surface of the chip 100 promotes its maintenance in the coating. Moreover, the fact that the disconnected strand 401a is secured to an individual pad 11a′ avoids untimely separation between said strand 401a and the chip 100.

The presence of one (or more) extension(s) 21a, 21b thus allows proper disconnection of two strands of wire from one another, without risk of damage to the chip 100, although the notch 130 is made in the surface of the chip 100. The coating ensures good mechanical attachment between the strands and the chip 100, the notch being located in the surface of the chip 100 and not on the outside as in the practice of the state of the art.

The invention is of course not limited to the embodiments and the examples described, and it is possible to make variant embodiments without departing from the scope of the invention as defined by the claims.

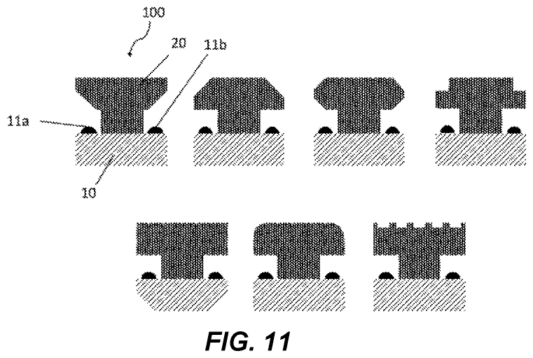

In particular, the manufacturing method according to the present invention allows the production of functional chips 100 whose cover 20 and support 10 have various shapes, as for example illustrated in FIG. 11, with beveled, rounded or crenellated edges, or with structures on a flat face. These particular shapes can provide all or some of the following advantages: the grip and hold of the encapsulating layer 120 limit the singular points (edges) likely to weaken the chip 100, simplify the gripping of the chips 100, limit the size and/or improve the integration of the functional chips in a final product. Of course, other shapes can be envisaged given the flexibility provided by the method.

1. Method for manufacturing a functional chip (100) comprising the following steps:
supplying a collective structure (200) formed by a cover substrate (220) assembled on a support substrate (210), said structure (200) defining a plurality of functional chips (100),
singulating the functional chips (100), each chip (100) comprising at least two electrical connection pads (11a, 11b) intended to be connected to wire elements (40a, 40b),
the manufacturing method being characterized in that:
the support substrate (210) comprises a plurality of microelectronic components (211), each belonging to a chip (100), and has, on its front face, at least two electrical connection pads (11a, 11b) associated with a microelectronic component (211), scribe lines (212) separating the microelectronic components (211) belonging to neighboring chips (100), and a first protective layer (213) placed on the microelectronic components (211) outside the scribe lines (212) and the connection pads (11a, 11b);
the cover substrate (220) comprises first portions (21), assembled to the front face of the support substrate (210) via an adhesive layer, and a second part (222) at a distance from the front face of the support substrate (210), each first portion (21) forming a spacer between two electrical connection pads (11a, 11b) of a microelectronic component (211);
functional chip (100) singulation comprises forming a mask (230) on a free face of the collective structure (200), defining protected zones (231) and unprotected zones (233), and comprises dry, plasma or reactive ion bombardment etching of the cover substrate (220) and of the support substrate (210), plumb with the unprotected zones (233);
the protected zones (231) being arranged either plumb with the first portions (21), or plumb with the first portions (21) and second portions (22) included in the second part (222) of the cover substrate (220), the second portions (22) extending opposite the electrical connection pads (11a, 11b) and being crenellated to allow access to said pads (11a, 11b) along an axis (z) normal to the front face of the support substrate (210).

2. Manufacturing method according to the preceding claim, wherein the support substrate (210) comprises a wafer made of semiconductor material, in particular silicon.

3. Manufacturing method according to one of the preceding claims, wherein the cover substrate (220) comprises a wafer made of semiconductor material, in particular silicon, or of insulating material, in particular glass or sapphire.

4. Manufacturing method according to one of the preceding claims, wherein the first portions (21) comprise, on flanks substantially normal to the front face of the support substrate (10), a second protective layer (214).

5. Manufacturing method according to one of the preceding claims, wherein the internal face, facing the front face of the support substrate (210), of the second part (222) of the cover substrate (220) comprises a second protective layer (214).

6. Manufacturing method according to one of the preceding claims, wherein the support substrate (210) and the cover substrate (220) each comprise a wafer made of semiconductor material of the same nature, and the dry etching of the functional chip (100) singulation step is done in a single treatment.

7. Manufacturing method according to one of the preceding claims, wherein, after the singulation of the functional chips (100), each chip (100) comprises a cover (20) from the cover substrate (220) and a support (10) from the support substrate (210), and the method then comprises a step of assembling each chip (100) with two wire elements (40a, 40b), each wire element (40a, 40b) being arranged in a groove (30a, 30b) delimited by a side of a first portion (21) of the cover (20) and a zone on the front face of the support (10) occupied by the electrical connection pad (11a, 11b), or by a second portion (22) of the cover (20), a flank of a first portion (21) of the cover (20) and a zone on the front face of the support (10) occupied by the electrical connection pad (11a, 11b).

8. Manufacturing method according to the preceding claim, comprising depositing a resin or polymer layer (120) on all or part of the chip (100) and on the wire elements (40a, 40b), to reinforce the mechanical strength between said chip (100) and said wire elements (40a, 40b).

9. Manufacturing method according to one of the preceding claims, wherein at least one microelectronic component (211) of a chip (100) comprises two pairs of electrical connection pads (11a, 11a′; 11b, 11b′), and wherein the first portion (21) of the cover substrate (220), which forms a spacer between said two pairs (11a, 11a′, 11b, 11b′), comprises an extension (21a) forming a second spacer between individual connection pads (11a, 11a′) of a pair of electrical connection pads (11a, 11a′).
